(19) United States
(12) Patent Application Publication
(10) Pub. No.: US 2026/0211029 A1
(43) Pub. Date: Jul. 23, 2026

(54) SYSTEM, ELECTRONIC APPARATUS AND STORAGE MEDIUM FOR CONTINUOUS TESTING OF ARRAY DEVICE

(71) Applicants: NANJING UNIVERSITY, Nanjing (CN); Hefei National Laboratory, Hefei (CN)

(72) Inventors: Weizong XU, Nanjing (CN); Tao MIAO, Nanjing (CN); Hai LU, Nanjing (CN); Fangfang REN, Nanjing (CN); Dong ZHOU, Nanjing (CN); Feng ZHOU, Nanjing (CN)

(21) Appl. No.: 19/452,983

(22) Filed: Jan. 20, 2026

(30) Foreign Application Priority Data
Jan. 23, 2025 (CN) 202510104344.5

(51) Int. Cl. G01R 31/28

(52) U.S. Cl. CPC G01R 31/2887

(57) ABSTRACT

A system for continuous testing of array device includes a first host computer and a probe station. The first host computer sends a scanning path to the probe station to control the probe station to perform scanning test on an array device to be tested; a tray of the probe station moves along path points set by the scanning path; after reaching a specified position, the tray moves upwards to connect a probe to an electrode of the array device to be tested; an electronic test apparatus tests the array device to be tested according to test instruction from a second host computer, and the foregoing process is repeated until all electrodes of the array device to be tested are tested.

### CROSS-REFERENCE TO RELATED APPLICATION

This patent application claims the benefit and priority of Chinese Patent Application No. 202510104344.5 filed with the China National Intellectual Property Administration on Jan. 23, 2025, the disclosure of which is incorporated by reference herein in its entirety as part of the present application.

### TECHNICAL FIELD

The present disclosure relates to the technical field of device test, and in particular to a system, electronic apparatus and storage medium for continuous testing of an array device.

### BACKGROUND

Conventional techniques for array device testing mainly rely on modeling an array shape to control a probe to connect to devices at different positions for batching testing. As multiple chips are distributed on one wafer, and multiple devices are distributed on one chip, the chips on the wafer or the devices on the chip are in an incompletely regular alignment state for some considerations during design, which can cause interval step sizes of devices to become irregular, making modeling difficult. This can certainly be solved by editing a nested scanning path. However, in this mode, the complexity of summarizing and organizing the test results of the entire array device increases significantly.

### SUMMARY

The present disclosure provides a system, electronic apparatus and storage medium for continuous testing of an array device, thereby solving the technical problem of complicated test mode setup and highly complex data summarization in an existing device testing method when faceting an incompletely regular or misaligned arrangement.

To solve the technical problem, the present disclosure provides a system for continuous testing of an array device, including a first host computer and a probe station;
where the first host computer is configured to send a scanning path to the probe station to control the probe station to perform a scanning test on an array device to be tested; a tray of the probe station moves along path points set by the scanning path; after reaching a specified position, the tray moves upwards to connect a probe to an electrode of the array device to be tested; and an electronic test apparatus is configured to test the array device to be tested according to a test instruction sent from a second host computer, and the foregoing process is repeated until all electrodes of the array device to be tested are tested.

Preferably, the first host computer is configured to control the tray of the probe station to move up, down, left and right through a script runtime environment and a communication instruction set provided by the probe station.

Preferably, the first host computer communicates with the second host computer via a control log.

Preferably, when the probe station performs the scanning test on the array device to be tested, a two-dimensional scanning path is imported from a library of the first host computer or newly created; a tray control unit of the first host computer is configured to generate a set of control instructions according to the scanning path and send a movement instruction to the probe station; the probe station controls the tray to complete the instruction and then feeds back position information to the first host computer; the first host computer writes the position information into the control log; after detecting that the log is updated, an apparatus control unit of the second host computer controls the electronic test apparatus to perform test according to predefined test parameters; on one hand, a detection result is combined with the position information to complete data summarization, and on an other hand, a “completion” signal is feed back to the control log to perform test for a next position; the tray control unit of the first host computer sends out a next instruction upon detecting the “completion” signal, and enters the next position for testing a next device; the foregoing operations are repeated until all instructions in the set of control instructions are completed, thereby completing the scanning test of a preset array.

Preferably, in an entire testing process, the second host computer aggregates all test data to complete data presentation, and saves all the test data after the test is fully completed.

Preferably, the scanning path comprises a minimum repeatable unit scanning path and a two-dimensional scanning path;
where the minimum repeatable unit scanning path is used for the array device with an incompletely periodic arrangement;
the two-dimensional scanning path is used for improving alignment accuracy between the probe and a device to be tested by a displacement compensation algorithm; and
the two-dimensional scanning path is compatible with a one-dimensional scanning scenario.

Preferably, the displacement compensation algorithm is used to correct a device spacing deviation caused by plastic deformation of a wafer where the array device is located by setting a deviation value.

Preferably, the minimum repeatable unit scanning path comprises a minimum nine-square unit, and the minimum nine-square unit is defined with Ux, Uy, unit, center_x=0, center_y=0, relative_points=[(0,0), (−unit,0), (−2*unit,0), (0,unit), (−unit+100,unit), (−2*unit−135,unit), (0,2*unit), (−unit,2*unit), (−2*unit,2*unit)], where Ux represents a length of the nine-square unit in an x direction; Uy represents a length of the nine-square unit in a y direction; unit represents a distance between individual devices in the nine-square unit, with an unit in micrometer; and center_x and center_y represent a center point position of an initial reference test device; and +100 and −135 represent relative deviations of a corresponding device.

The present disclosure further provides an electronic apparatus, including a memory, a processor, and a computer, where a computer program is stored in the memory and configured to be executed by the processor to implement the foregoing system.

The present disclosure further provides a computer-readable storage medium, where a computer program is stored in the computer-readable storage medium, and the computer program, when executed by a processor, is configured to implement the foregoing system.

Beneficial effects of the present disclosure at least include the follows. The first host computer and the second host computer in the system for continuous testing of the array device according to an embodiment of the present disclosure can coordinate the automatic probe station with the electronic test apparatus during mutual communication, to achieve continuous scanning test on an array device to be tested, thereby generating a test result. The second host computer may also obtain a detection position of a device to be tested through the control log, a test result of each position corresponds to its position, the quality of the result is marked with different colors, and the results are saved in EXCEL. Thus, this solution can implement scanning test with any test parameter for any array device, and then perform data visualization by combining detection position coordinates and a test result of the position, thereby providing comprehensive and effective test data for array devices with different shapes.

### BRIEF DESCRIPTION OF THE DRAWINGS

FIG. 1 is a flowchart of an implementation process of a system according to an embodiment of the present disclosure;

FIG. 2 is a structure connection diagram of the system according to an embodiment of the present disclosure;

FIG. 3 is a diagram of an internal communication structure of the system according to an embodiment of the present disclosure;

FIG. 4 is a structural diagram of an array device and its minimum repeatable unit according to an embodiment of the present disclosure;

FIG. 5 is a result diagram of scanning test of the array device according to an embodiment of the present disclosure; and

FIG. 6 is a diagram of an intermediate process of scanning test of the array device according to an embodiment of the present disclosure.

### DETAILED DESCRIPTION OF THE EMBODIMENTS

The following clearly and completely describes the technical solutions in the embodiments of the present disclosure with reference to the accompanying drawings in the embodiments of the present disclosure. Apparently, the described embodiments are merely a part rather than all of the embodiments of the present disclosure. All other embodiments obtained by a person of ordinary skill in the art based on the embodiments of the present disclosure without creative efforts shall fall within the protection scope of the present disclosure.

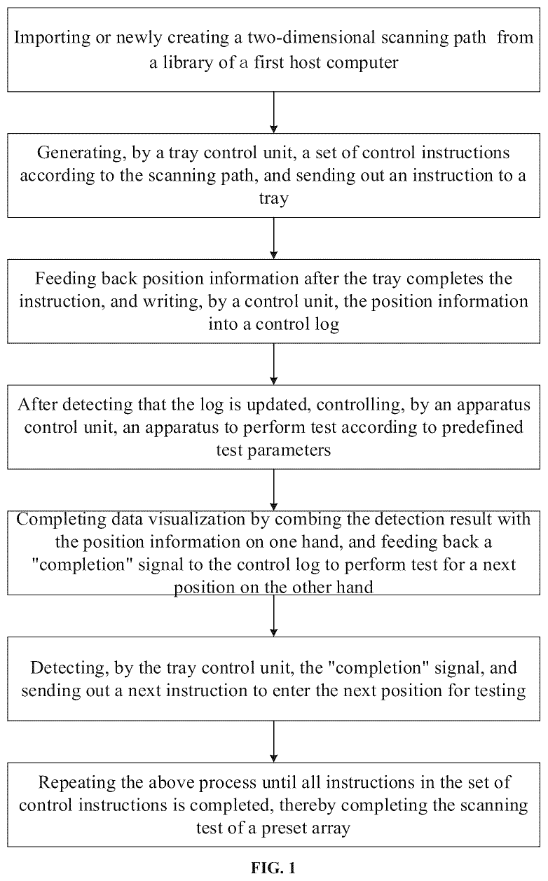

As shown in FIG. 1, an embodiment of the present disclosure provides a system for continuous testing of an array device, including a first host computer and a probe station.

The first host computer sends a scanning path to the probe station to control the probe station to perform scanning test on an array device to be tested. A tray of the probe station moves along path points set by the scanning path; after reaching a specified position, the tray moves upwards to connect a probe to an electrode of the array device to be tested; and an electronic test apparatus is configured to test the array device to be tested according to a test instruction sent from a second host computer, and the foregoing process is repeated until all electrodes of the array device to be tested are tested.

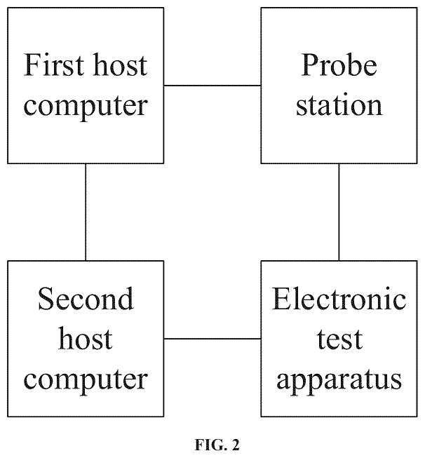

Specifically, the system structure connection is as shown in FIG. 2, including the first host computer, the second host computer, the probe station, and the electronic test apparatus. The probe station is connected to the electronic test apparatus, the probe station is connected to the first host computer, the electronic test apparatus is connected to the second host computer, and the first host computer is connected to the second host computer.

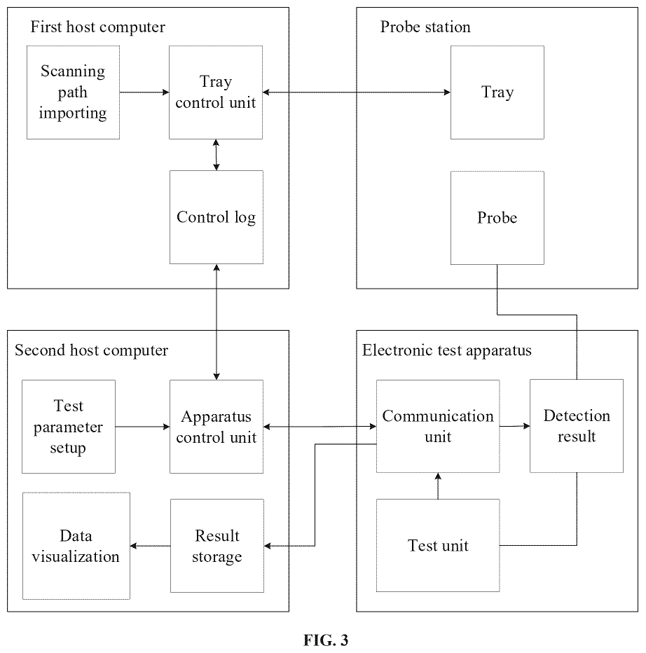

FIG. 3 shows units and control directions included in each result in the system. Specifically, a two-dimensional scanning path is imported from a library of the first host computer or newly created. A tray control unit on the first host computer is configured to generate a set of control instructions according to the scanning path and send one instruction to the tray of the probe station. The tray feeds back position information after completing the instruction, and the tray control unit writes the position information into a control log. After detecting that the control log is updated, an apparatus control unit on the second host computer controls the electronic test apparatus to perform test according to predefined test parameters. A detection result, on the one hand, is stored and then data visualization is achieved by combining with the position information, and on the other hand, a “completion” signal is feed back to the control log to perform test for a next position. The tray control unit sends out a next instruction upon detecting the “completion” signal, and enters the next position for testing the next device. The foregoing operations are repeated until all instructions in the set of control instructions are completed, thereby completing the scanning test of a preset array.

In this embodiment, the first host computer is any computer equipment with a communication protocol or software for the probe station, which is configured to control a tray part of the probe station to move up and down, and left and right, by means of a script runtime environment provided by a probe station manufacturer and a communication instruction set provided in the operating specification.

As the probe on the probe station is connected to the electronic test apparatus, it is often difficult to translate the probe integrally. Therefore, the array device is traversed by keeping the probe stationary and moving the underlying tray in the opposite direction in the present embodiment.

The first host computer is provided with a scanning path library for storing different scanning paths, thereby enabling convenient reuse by testing personnel. In consideration of the variety of the scanning paths, a mode of overlaying a scanning path on a minimum repeatable unit is particularly adopted to enhance program adaptability. In other words, a final scanning path may be in a path-in-path pattern.

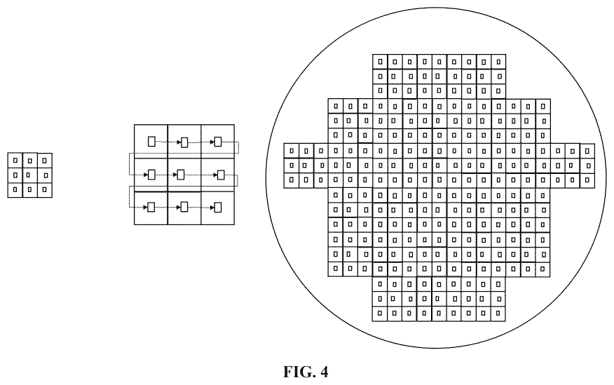

According to an embodiment of the present disclosure, a structural diagram of the array device and its minimum repeatable unit is taken as an example for illustration. As shown in FIG. 4, the minimum repeatable unit of the array device is a nine-square grid composed of nine devices. However, the electrodes of the devices are not all located at the same position of the devices, that is, it is impossible to complete a series of scanning tests through simple linear repetition. In this case, the nine-square grid needs to be modeled as the minimum repeatable unit and to be integrated with the scanning path of the array device to complete matching. In this case, a nine-square model is as follows: Ux=20000, Uy=20005, unit=6666, center_x=0, center_y=0, relative_points=[(0,0), (−unit,0), (−2*unit,0), (0,unit), (−unit+100,unit), (−2*unit−135,unit), (0,2*unit), (−unit,2*unit), (−2*unit,2*unit)].

Ux=20000 represents a length of the nine-square grid in an x direction; Uy=20005 represents a length of the nine-square grid in a y direction; unit=6666 represents a distance between individual devices in the nine-square grid, with an unit in micrometer; and center_x and center_y represent a center point position of an initial reference test device in the upper left corner.

Relative positions of the other eight devices relative to the reference device are calibrated. It should be noted that this scanning is performed from an upper left corner to a lower right corner of the wafer, resulting in a phenomenon that x-coordinate is-unit in a position relation formula, because this requires the tray carrying the wafer thereon to move in a negative direction. The scanning path is generated by setting indentation of each row and the number of nine-square grids in each row. For example, a scanning path of the array device as shown in FIG. 4 can be completed by inputting parameters (2,3), (1,5), (0,7), (1,5), (1,5) and (2,3), where (2,3) represents that two repeatable units are indented in the first row, followed by three repeatable units. The generated scanning points are positions1=[(0,0), (−1,0), (−2,0), (1,1), (0,1), (−1,1), (−2,1), (−3,1), (2,2), (1,2), (0,2), (−1,2), (−2,2), (−3,2), (−4,2), (1,3), (0,3), (−1,3), (−2,3), (−3,3), (1,4), (0,4), (−1,4), (−2,4), (−3,4), (0,5), (−1,5), (−2,5)].

It should be noted that if parameters input by a user are (12,3), (11,4), (10,5), (11,4), (11,4), (12,3), the program may still generate the same scanning points (positions1), because the scanning points record a relative relationship of positions, and the simultaneous increase of the indentation of each row does not affect the relative relationship. If the user slices the wafer, for example, by cutting off the right two columns of the wafer to change a shape of the array to be tested, new parameters, such as (2,3), (1,4), (0,5), (1,4), (1,4) and (2,3), need to be input. The generated scanning points are positions2=[(0,0), (−1,0), (−2,0), (1,1), (0,1), (−1,1), (−2,1), (2,2), (1,2), (0,2), (−1,2), (−2,2), (1,3), (0,3), (−1,3), (−2,3), (1,4), (0,4), (−1,4), (−2,4), (0,5), (−1,5), (−2,5)].

These scanning paths can be saved in the scanning path library for direct use next time, and the naming of “positions” can be determined according to the preference of the user. Herein, each point in positions1 and positions2 corresponds to one minimum repeatable unit (i.e., one nine-square grid). Therefore, when the 23 points in positions1 are completed, the scanning test of all 207 devices (23×9=207) in the entire array is completed. If the user needs to scan an array with a more irregular shape, the scanning points can also be described by directly editing “positions” instead of being generated by inputting parameters, and coordinates in “positions” may be decimals. When moving among devices at different positions, a tray control program first lowers the tray by 500 μm, and then moves the tray, and after reaching a corresponding position, the tray is raised by 500 μm to bring the probe back into contact with the electrode of the device, which prevents both the probe tip and device from damage.

After the tray reaches each new device position, the tray control unit sends message=‘Test Python logging to Velox({ }, { })’. format(position_number, relation_number) to the control log, and position_number and relation_number are determined according to specific values, where position_number<23, and relation_number<9. For example, Test Python logging to Velox(15,4) means the fourth device in the fifteenth nine-square grid. The full compatibility of the foregoing two-dimensional scanning with a one-dimensional scenario means that the scanning test of a row of 128 devices can be completed simply by enabling relative_points=[(0, 0)] and then setting an input parameter as (0, 128).

The electrode on each device is a square with a side length of 80 μm, and if a predetermined position of the probe is set to the center of the electrode, an allowable error is ±40 um. If the probe needs to make better contact with the electrode, it needs to ensure that the probe does not exceed ±20 μm from the center point of the electrode. A minimum displacement distance of the tray on the probe station is 4 μm, which is sufficient to complete the task theoretically. However, as a side length of the nine-square grid is 20,000 μm, the displacement of the outermost nine-square grid is (−40,000, 100,000), a slight deformation of the wafer will lead to a significant error when determining the position of the last device—in the y-direction, the allowable deformation is 20/100,000=2 per ten thousand (2 [symbol] ). In addition, due to two-dimensional scanning, the resulting errors are cumulative, which further amplifies uncertain factors. Therefore, a displacement compensation algorithm for different deformations is born at the right moment. Displacement deviation scenarios considered in the program include an in-plane displacement deviation caused by wafer warpage and non-orthogonality in x and y directions caused by tape-out. The in-plane displacement deviation caused by wafer warpage refers to a phenomenon that during production or use, two points separated by L μmin a plane will deviate from the original plane due to slight convexity of the wafer, and the distance between the two points is slightly less than L um, with a specific value depending on the warpage degree. The non-orthogonality in x and y directions caused by tape-out is also unique to the two-dimensional scanning, which means that when the devices are aligned in the x direction, a connection line among the devices in the same column is not perpendicular to this x direction. In this embodiment, an included angle between x and y axes of the wafer is slightly greater than 90 degrees, so when the tray moves toward a positive direction of y axis, the next device may appear to the left of its expected position. As this error value is proportional to the displacement in the direction and the same batch of wafers have a consistent error ratio, it can be ruled out as an accidental error.

In this embodiment, the displacement compensation algorithm includes a step of pre-scanning before formal scanning. The pre-scanning is carried out under the condition of light illumination, and only a first device of each nine-square grid is scanned. Therefore, a step size of the pre-scanning is 20,000 μm, and image information under the microscope is read at each new position. Feature matching and comparison are performed using BFMatcher to obtain the deviation relative to a first image, and a displacement of the device position is recorded as δx and δy. A total of 23 δx and δy values are stored in a same group. When the formal scanning is performed, the displacement of the tray will be superimposed with δx and δy on the basis of x*20,000 μm and y*20,000 μm to ensure that the probe is in a relative center position of the electrode. It can be considered that other eight devices in each nine-square grid have the same compensation amount as the first device, which are not calibrated separately to save the time.

In a case that accurate alignment of the position is achieved, the second host computer is required to complete different parameter testing and data processing of the position. In this embodiment, a keithley 2636B source test unit is used as the electronic test apparatus, the apparatus is connected to the second host computer through a USB (universal serial bus), but other connection modes can achieve the same effect with simple modification. It should be noted that the program in the second host computer can only require a slight modification to complete the control for other electronic test apparatus that can be controlled by the instructions of the host computer. Before the apparatus control unit of the second host computer, there are some initialization parts first. During program running, a pop-up window may prompt the user to specify a storage address for the test data of this time, facilitating subsequent review.

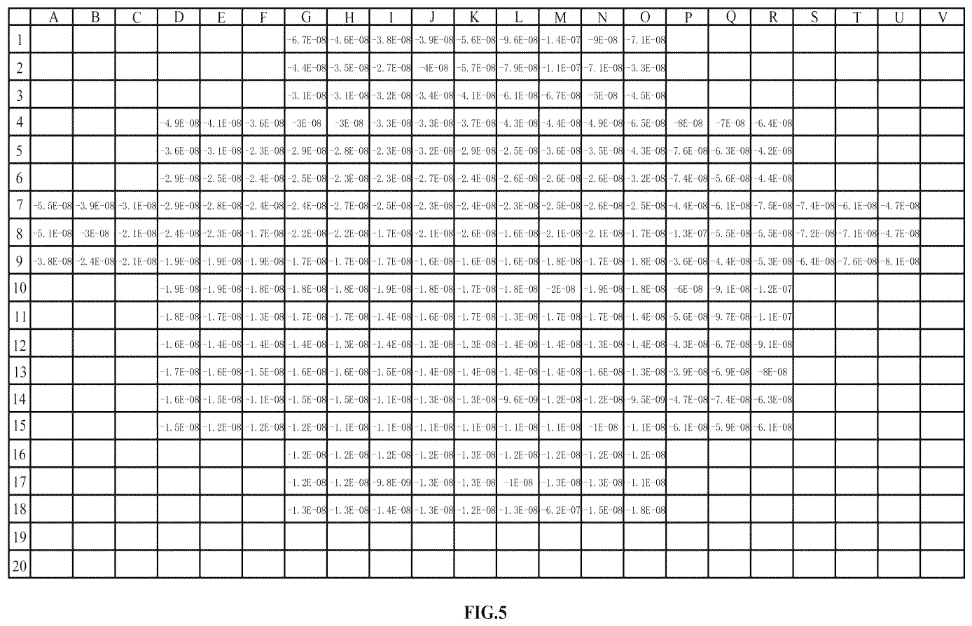

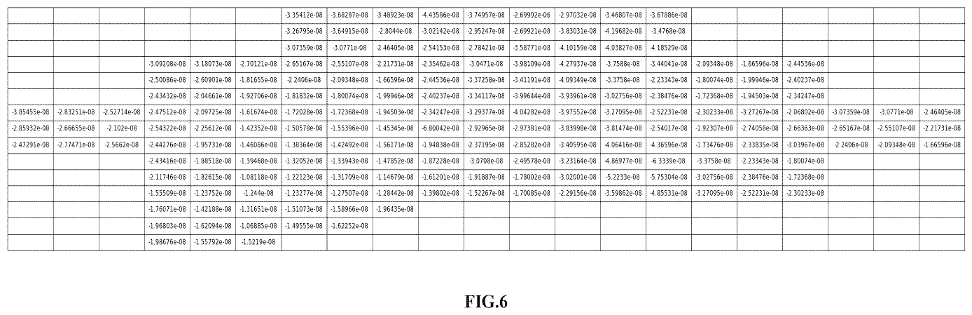

In this embodiment, reverse bias dark current test for a Si-based PIN device is performed using Model 2636B, requiring an apparatus address to be given. In this embodiment, instrument_address=“usb0:: 0x05e6:: 0x2636:: 4544659:: instr”, and this address is unique and fixed for each apparatus. Afterwards, communication with the apparatus is attempted to be established, such as instrument=rm. open_resource (instrument_address); instrument. timeout=10000; print(“Instrument opened successfully!”). Apparatus timeout is set to 10,000 ms (i.e., 10 s), because the 2636 source meter needs a longer test time during the testing of a weak current, and if the timeout period is not manually increased, frequent error reporting may occur, failing to read data. It should be noted that the timeout refers to a maximum waiting time, not the time required to test each data point. Test parameter setup is an enumeration method: voltages=[−30, −60, −90, −120, −150, −180, 2]. The test parameter setup can be modified arbitrarily, such as by reducing the step size, but increasing the test time, or an analytical method may also be used for expression, such as, for voltage in range (2,−181,−2) which means that the step size from 2V to −180V is −2V. The program can perform the following operations according to each voltage test point: instrument.write(f“smua.source.levelv={voltage}”); instrument.write(“printnumber(smua.measure.iv( ))”), a voltage is written into 2636 and then an actual voltage and current are input to a communication unit, and then this data is read to the second host computer through response=instrument.read ( ); simultaneously, print(f“Voltage: {voltage} V, RealVoltage:{realvoltage} V, Current:{current} A”) is displayed in a program interaction window for the user to rapidly determine whether the data is reasonable. As a test environment needs to be in a dark scenario, “2V” is used to determine whether the device is normal and whether the probe is in good contact with the electrode. In this case, the actual voltage often does not reach 2V, because an on-state current of the device is higher than a limit current set by the 2636 source meter, so the source meter increases an internal resistance to reduce the current to the limit current, which also divides a total voltage of 2V to make a measured voltage across the device less than 2V. After the set voltage to be tested is tested, a storage unit in the second host computer may associate the test data with (15, 4) by using def check_file(shared_file_path) function in combination with the position information “Test Python logging to Velox(15,4)” read from the control log, and then save the data to an Excel file named “measure_15_4.xlsx”. In the visualization part of the data, it is only necessary to modify a feature value required to be extracted, for example, by setting voltage_value=−180 in specific_row=df[df[‘Voltage(V)’]==voltage_value], the program can index to the required row to extract a corresponding current test result and position data of the device in the whole array, and then the current test results of all devices at −180V and their positions are correspondingly output to a new EXCEL one by one, and are marked with color-magnitude rules to form a result shown in FIG. 5. FIG. 6 is a diagram of a real-time summarization result intercepted at a random moment in an actual measurement process, that is, the test process of the whole array device is completed.

Various technical features of the foregoing embodiments may be combined arbitrarily. For the sake of brevity, all possible combinations of the technical features in the foregoing embodiments are not described, only the preferred embodiments of the present disclosure are expressed, of which description is more specific and detailed, but it should not be understood as limiting the scope of the present disclosure. The combinations of these technical features should be considered to be within the scope recorded in this specification as long as there is no contradiction therebetween.

It should be pointed out that several variants and improvements may also be made by those of ordinary skill in the art without departing from the conception of the present disclosure, and all fall within the protection scope of the present disclosure. Therefore, the protection scope of the present disclosure shall be subject to the appended claims.

What is claimed is:

1. A system for continuous testing of an array device, comprising a first host computer and a probe station, wherein
the first host computer is configured to send a scanning path to the probe station to control the probe station to perform a scanning test on an array device to be tested; a tray of the probe station moves along path points set by the scanning path; after reaching a specified position, the tray moves upwards to connect a probe to an electrode of the array device to be tested; and an electronic test apparatus is configured to test the array device to be tested according to a test instruction sent from a second host computer, and the foregoing process is repeated until all electrodes of the array device to be tested are tested;
wherein the first host computer communicates with the second host computer via a control log;
when the probe station performs the scanning test on the array device to be tested, a two-dimensional scanning path is imported from a library of the first host computer or newly created;
a tray control unit of the first host computer is configured to generate a set of control instructions according to the scanning path and send a movement instruction to the probe station; the probe station controls the tray to complete the instruction and then feeds back position information to the first host computer; the first host computer writes the position information into the control log; after detecting that the log is updated, an apparatus control unit of the second host computer controls the electronic test apparatus to perform test according to predefined test parameters; on one hand, a detection result is combined with the position information to complete data summarization, and on an other hand, a “completion” signal is feed back to the control log to perform test for a next position; the tray control unit of the first host computer sends out a next instruction upon detecting the “completion” signal, and enters the next position for testing a next device; the foregoing operations are repeated until all instructions in the set of control instructions are completed, thereby completing the scanning test of a preset array.

2. The system for continuous testing of the array device according to claim 1, wherein the first host computer is configured to control the tray of the probe station to move up, down, left and right through a script runtime environment and a communication instruction set provided by the probe station.

3. The system for continuous testing of the array device according to claim 1, wherein in an entire testing process, the second host computer aggregates all test data to complete data presentation, and saves all the test data after the test is fully completed.

4. The system for continuous testing of the array device according to claim 1, wherein the scanning path comprises a minimum repeatable unit scanning path and a two-dimensional scanning path;
wherein the minimum repeatable unit scanning path is used for the array device with an incompletely periodic arrangement;
the two-dimensional scanning path is used for improving alignment accuracy between the probe and a device to be tested by a displacement compensation algorithm; and
the two-dimensional scanning path is compatible with a one-dimensional scanning scenario;
wherein the displacement compensation algorithm is used to correct a device spacing deviation caused by plastic deformation of a wafer where the array device is located by setting a deviation value;
wherein the minimum repeatable unit scanning path comprises a minimum nine-square unit, and the minimum nine-square unit is defined with Ux, Uy, unit, center_x=0, center_y=0, relative_points=[(0,0), (−unit,0), (−2*unit,0), (0,unit), (−unit+100,unit), (−2*unit−135,unit), (0,2*unit), (−unit,2*unit), (−2*unit,2*unit)], wherein Ux represents a length of the nine-square unit in an x direction; Uy represents a length of the nine-square unit in a y direction; unit represents a distance between individual devices in the nine-square unit, with an unit in micrometer; and center_x and center_y represent a center point position of an initial reference test device; and +100 and −135 represent relative deviations of a corresponding device.

5. An electronic apparatus, comprising a memory, a processor, and a computer, wherein a computer program is stored in the memory and configured to be executed by the processor to implement the system according to claim 1.

6. The electronic apparatus according to claim 5, wherein the first host computer is configured to control the tray of the probe station to move up, down, left and right through a script runtime environment and a communication instruction set provided by the probe station.

7. The electronic apparatus according to claim 5, wherein in an entire testing process, the second host computer aggregates all test data to complete data presentation, and saves all the test data after the test is fully completed.

8. The electronic apparatus according to claim 5, wherein the scanning path comprises a minimum repeatable unit scanning path and a two-dimensional scanning path;
wherein the minimum repeatable unit scanning path is used for the array device with an incompletely periodic arrangement;
the two-dimensional scanning path is used for improving alignment accuracy between the probe and a device to be tested by a displacement compensation algorithm; and
the two-dimensional scanning path is compatible with a one-dimensional scanning scenario;
wherein the displacement compensation algorithm is used to correct a device spacing deviation caused by plastic deformation of a wafer where the array device is located by setting a deviation value;
wherein the minimum repeatable unit scanning path comprises a minimum nine-square unit, and the minimum nine-square unit is defined with Ux, Uy, unit, center_x=0, center_y=0, relative_points=[(0,0), (−unit,0), (−2*unit,0), (0,unit), (−unit+100,unit), (−2*unit−135,unit), (0,2*unit), (−unit,2*unit), (−2*unit,2*unit)], wherein Ux represents a length of the nine-square unit in an x direction; Uy represents a length of the nine-square unit in a y direction; unit represents a distance between individual devices in the nine-square unit, with an unit in micrometer; and center_x and center_y represent a center point position of an initial reference test device; and +100 and −135 represent relative deviations of a corresponding device.

9. A computer-readable storage medium, wherein a computer program is stored in the computer-readable storage medium, and the computer program, when executed by a processor, is configured to implement the system according to claim 1.

10. The computer-readable storage medium according to claim 9, wherein the first host computer is configured to control the tray of the probe station to move up, down, left and right through a script runtime environment and a communication instruction set provided by the probe station.

11. The computer-readable storage medium according to claim 9, wherein in an entire testing process, the second host computer aggregates all test data to complete data presentation, and saves all the test data after the test is fully completed.

12. The computer-readable storage medium according to claim 9, wherein the scanning path comprises a minimum repeatable unit scanning path and a two-dimensional scanning path;
wherein the minimum repeatable unit scanning path is used for the array device with an incompletely periodic arrangement;
the two-dimensional scanning path is used for improving alignment accuracy between the probe and a device to be tested by a displacement compensation algorithm; and
the two-dimensional scanning path is compatible with a one-dimensional scanning scenario;
wherein the displacement compensation algorithm is used to correct a device spacing deviation caused by plastic deformation of a wafer where the array device is located by setting a deviation value;
wherein the minimum repeatable unit scanning path comprises a minimum nine-square unit, and the minimum nine-square unit is defined with Ux, Uy, unit, center_x=0, center_y=0, relative_points=[(0,0), (−unit,0), (−2*unit,0), (0,unit), (−unit+100,unit), (−2*unit−135,unit), (0,2*unit), (−unit,2*unit), (−2*unit,2*unit)], wherein Ux represents a length of the nine-square unit in an x direction; Uy represents a length of the nine-square unit in a y direction; unit represents a distance between individual devices in the nine-square unit, with an unit in micrometer; and center_x and center_y represent a center point position of an initial reference test device; and +100 and −135 represent relative deviations of a corresponding device.
